(19) United States
(12) Patent Application Publication
(10) Pub. No.: US 2012/0255614 A1
(43) Pub. Date: Oct. 11, 2012

(54) Increased Near-Infrared Light Harvesting in Dye-Sensitized Solar Cells using Co-sensitized Energy Relay Dyes on Titania

(76) Inventors: Brian E. Hardin, Stanford, CA (US); Michael D. McGehee, Palo Alto, CA (US)

(21) Appl. No.: 13/423,516

(22) Filed: Mar. 19, 2012

Related U.S. Application Data
(60) Provisional application No. 61/516,833, filed on Apr. 8, 2011.

(51) Int. Cl. H01L 51/46

(52) U.S. Cl. 136/263

(57) ABSTRACT

A solar cell having increased near-infrared (NIR) light harvesting is provided that includes a container comprising an optically transparent top surface and a bottom surface, where a cavity is disposed between the top surface and the bottom surface, a first electrode connected to the top surface, a second electrode connected to the bottom surface, and an NIR dye cosensitized with a metal complex sensitizing dye (SD) disposed in the cavity that absorbs NIR light, where the NIR light undergoes energy transfer to the metal complex dyes that separates the charges and produces photocurrent.

### CROSS-REFERENCE TO RELATED APPLICATIONS

This application claims priority from U.S. Provisional patent application Ser. No. 61/516,833 filed Apr. 8, 2011, which is incorporated herein by reference.

### STATEMENT OF GOVERNMENT SPONSORED SUPPORT

This invention was made with Government support under contract N00014-08-1-1163 awarded by Office of Naval Research (ONR). The Government has certain rights in this invention.

### FIELD OF THE INVENTION

The present invention relates generally to solar cells. More particularly, the invention relates to increasing near-infrared (NIR) light harvesting in state-of-the-art dye-sensitized solar cells using energy transfer in a co-sensitized system, where both an NIR dye and a metal complex sensitizing dye are attached to the surface of titania.

### BACKGROUND OF THE INVENTION

Currently, the state-of-the-art dye-sensitized solar cells (DSCs) are only 11% efficient due to incomplete light harvesting in the near-infrared portion of the solar spectrum. DSCs use sensitizing dyes, which attach on the titania and separate charges at the titania/electrolyte interface, to absorb sunlight. It is very challenging to absorb light in the near-infrared and still be able to separate charges. What is needed is a DSC that absorbs sunlight and transfers the energy to a neighboring sensitizing dye that is responsible for charge separation.

### SUMMARY OF THE INVENTION

A solar cell having increased near-infrared (NIR) light harvesting is provided that includes a nanostructured semiconductor, a hole conducting medium, wherein said hole conducting medium comprises an electrolyte medium or a solid-state medium, a pair of electrodes, and a dye cosensitized with a metal complex sensitizing dye that absorbs NIR light, where the NIR light undergoes energy transfer to the metal complex dye that separates charges and produces photocurrent to the electrode.

### BRIEF DESCRIPTION OF THE DRAWINGS

FIG. 1 shows a solar cell having increased near-infrared (NIR) light harvesting, according to one embodiment of the invention.

### DETAILED DESCRIPTION

According to the invention, a near-infrared absorbing dye is attached to the titania that absorbs sunlight and transfers the energy to a neighboring sensitizing dye that is responsible for charge separation. Using near-infrared absorbing energy, relay dyes will extend light absorption into the near infrared and increase the power conversion efficiency from 11% to 13%. Low efficiency DSCs are currently commercialized, however increasing the power conversion by >15% would greatly increase the market competitiveness of DSCs. It is also important to note that the current invention does not require any additional processing steps, resulting in a negligible cost difference.

NIR energy, for example between 700-1000 nm, relay dyes are lightly co-sensitized (5-15% of the titania surface) with metal complex dyes (85-95% of titania surface), which produce world record efficiencies but that do not absorb light strongly in the near-infrared portion of the solar spectrum.

Cosensitization of broadly absorbing Ruthenium metal complex dyes with highly absorptive nearinfrared (NIR) organic dyes is a clear pathway to increase light harvesting in liquid based DSCs. In cosensitized DSCs, dyes are intimately mixed and intermolecular charge and energy transfer processes play an important role in device performance. According to the invention, an organic NIR dye incapable of hole regeneration is able to produce photocurrent via intermolecular energy transfer with an average excitation transfer efficiency of over 25% when cosensitized with a metal complex sensitizing dye (SD).

The current invention is disposed to increase NIR light harvesting in dye-sensitized solar cells by co-sensitizing the titania surface with energy relay dyes, which absorb NIR light and undergoes energy transfer to the metal complex dyes that separates the charges and produces photocurrent.

In one aspect, the current invention can be used with Dye-sensitized solar cells, organic solar cells, and any nanostructured solar cell.

In another aspect the current invention operates if the dyes are very close to one another (i.e. <2 nm). In one aspect of the invention, the NIR energy relay dye is within 1-2 nanometers of a functional sensitizing dye. The NIR energy relay dye is directly attached to the sensitizing dye, for example where the sensitizing dye is also covalently bonded to the titania. In another aspect, the he NIR dye is covalently bonded to the sensitizing dye. Conversely, putting the near-infrared energy relay dye inside the electrolyte would not result in meaningful improvement.

The invention provides increased near-infrared light harvesting in a state-of-the-art dye-sensitized solar cell using energy transfer in a co-sensitized system. Unlike the previous attempts, this invention includes a red-shifted dye that is able to efficiently undergo energy transfer and contribute to the photocurrent. The invention greatly reduces the design rules of the near-infrared dye.

This type of NIR sensitization can be used for both for solar cells and also photodetectors (e.g. night vision) to boost the signal and enhance NIR spectral sensitivity.

S1 Synthesis and Yield of AS02 and C106

C106 Synthesis

Synthesis and yield of C106 has been previously described in literature.¹_ENREF_{—}1

Instrument and Materials for AS02

NMR spectra were recorded on a Varian Inova 300 operating at 300 MHz. Gel permeation chromatography was performed using a Polymer Laboratories (Varian) PL-GPC 50 Plus Integrated System with three in-line PL mixed E columns.

All chemicals were purchased from commercial suppliers and used without further purification. Compound 1 was purchased from TCI America. Column chromatography was performed using silica gel mesh size (230-400).

Synthesis Scheme 1

Compound 2-t-butyl 3-(6,7-dicyanonaphthalen-2-yl)acrylate: 6-bromonaphthalene-2,3-dicarbonitrile (1) (0.50 g, 1.94 mmol) and bis(tri-t-butylphosphine) palladium(0) (Pd[P(tBu)₃]₂) (0.04 g, 0.078 mmol, 4 mol %) were added to a 50 mL schlenk flask and subjected to three vacuum/nitrogen refill cycles. To the nitrogen filled schlenk flask were added t-butyl acrylate (0.32 mL, 2.18 mmol), dicyclohexylmethylamine (NCy₂CH₃) (0.46 mL, 2.15 mmol), and THF (15 mL, anhydrous). The reaction mixture was allowed to stir at room temperature for 5 min then heated to 70° C. in an oil bath for 16 h. Precipitates together with a deep blue/violet fluorescence began to form after 10 min. After the reaction was complete, via TLC analysis, the THF was removed using a rotary evaporator to provide a grey solid that was washed with cold methanol, filtered, and dried under vacuum. The solid was dissolved in minimal THF and filtered through a 1 micron glass fiber filter, followed by THF removal to provide an off-white solid that was vacuum dried and used without further purification. (0.495, 84%) ¹H NMR (CDCl₃, 300 MHz): d(ppm) 8.34 (2H, d, J=5.10 Hz, ArH), 7.98 (3H, m, ArH), 7.73 (1H, d, J=15.9 Hz, vinyl H), 6.58 (1H, d, J=15.9 Hz, vinyl H), 1.56 (9H, s, OC(CH₃)₃).

Compound 3—t-butyl 3-(6,7-dicyanonaphthalen-2-yl)propanoate: Compound 2 (0.25 g, 0.82 mmol), and Pd/C (0.05 g) were added to a 50 mL schlenk flask followed by THF (20 mL) and methanol (2 mL). The reaction mixture was heated to 40° C. for 10 min until 3 dissolved, then cooled to room temperature and triethylsilane (1.30 mL, 8.21 mmol) was added. A mild evolution of H₂ was observed during the first hour at which point the reaction was heated slightly to 40° C. overnight to complete reaction as determined by TLC. The reaction mixture was filtered through a 1 micron glass fiber filter and the solvent removed by rotary evaporation to provide a pale green oil that crystallized. The solid was stirred/washed with 3×2 mL hexane, followed by drying in a vacuum oven to provide an off-white solid (0.18 g, 72%). ¹H NMR (CDCl₃, 300 MHz): d(ppm) 8.29 (2H, d, J=12.3 Hz, ArH), 7.91 (2H, d, J=8.40 Hz, ArH), 7.78 (1H, s, ArH), 7.67 (1H, d, J=8.55 Hz, ArH), 3.15 (2H, t, J=7.50 Hz, CH₂), 2.66 (2H, t, J=7.50 Hz, CH₂) 1.40 (9H, s, OC(CH₃)₃).

Compound 4: Compound 3 (0.180 g, 0.60 mmol), and zinc acetate (Zn(OAc)₂.2H₂O) (0.044 g, 0.20 mmol) were added to a 25 mL schlenk flask followed by 1-hexanol (10 mL) and this was heated at 90° C. for 10 min. 1,8-diazabicyclo[5.4.0]undec-7-ene (DBU) (0.33 mL, 2.21 mmol) was added and the reaction mixture was heated to 160° C. for 16 h resulting in a dark green reaction mixture. The solvent was removed and THF (7 mL) followed by 1 M NaOH (2 mL) were added and this was heated at 70° C. for 20 h The solvent was removed and the residue dissolved in DI-H₂O (15 mL) and refluxed for 1 h. The resultant green solution was filtered through a 1 micron glass fiber filter and neutralized with conc. acetic acid. The precipitate was filtered and washed with copious amounts of DI-H₂O then dried under vacuum at 80° C.

S2 Photo-Electron Spectroscopy in Air (PESA) of AS02

PESA was performed on a Riken Keiki PESA AC-2 model with methods previously used to determine the HOMO levels of sensitizing dyes.⁴ PESA measurement shown in figure S2 of provisional application 61/516,833 filed Apr. 8, 2011, which is incorporated herein by reference, indicates that the HOMO level of AS02 is −4.60 eV.

Figure S2 of provisional application 61/516,833 filed Apr. 8, 2011, which is incorporated herein by reference, shows square root of photoelectric quantum yields against incident photon energies for AS02 measured using PESA.

S3 Calculating the FRET Ro between AS02 and C106

The FRET radius, or the distance in which Förster energy transfer is 50% probable between individual chromophores, can be calculated using equation S1.⁵

$${R}_{o}^{6} = \frac{9000 \cdot ln ( 10 ) {κ}^{2} {Q}_{D}}{128 \cdot {π}^{5} {n}^{4} {N}_{A}} \int {F}_{D} ( λ ) {ɛ}_{A} ( λ ) {λ}^{4} d λ \qquad ( S 1 )$$

Where n is the index of refraction of the host medium (1.4-1.5 for the DSC electrolyte), κ₂ is the orientational factor (⅔ for random orientation), N_{A} is Avogadro's number, Q_{D} is the photoluminescence efficiency, F_{D} is the normalized emission profile of the donor, and ε(λ) is the molar extinction coefficient.

The FRET R₀ from AS02 to C106 is between 1.5 to 1.8 nm based on a AS02 photoluminescence quantum efficiency range between 10-30% and the emission and absorption overlap spectra shown in Figure S1 of provisional application 61/516,833 filed Apr. 8, 2011, which is incorporated herein by reference.⁶ Because the FRET radius goes as the wavelength to the fourth power (λ⁴) it is possible to get rather sizable (>1.5 nm) radii even if the NIR-ERD emits into a weakly absorbing portion of the sensitizing dye. Blue-shifting the emission spectrum by 30 nm and 50 nm result in a FRET R₀ of 2.6 nm and 3 nm respectively.

Despite the strong overlap in C106 emission with AS02 absorption, the FRET R₀ from C106 to AS02 is only around 1.5-2.2 nm. The moderate FRET R₀ is a result of the very low photoluminescence quantum efficiency of C106.

S4 Titania Film preparation and DSC Fabrication

Show Denko 17-nm-diameter particles were deposited on fluorine-doped tin oxide glass (TEC 15 Ω/square, 2.2 mm thick, Pilkington) via screen printing and sintered at 450° C. Films were subsequently dipped in hot (70° C.) TiCl₄ for 30 minutes, rinsed in H2O and heated at 450° C. for 10 minutes before being immersed in the dye(s) solution(s); see manuscript for specific sensitization methods. The preparation of the platinum counter-electrode on fluorine-doped tin oxide glass (TEC 15 Ω/square, 2.2 mm thick, Pilkington) is described previously.⁷ Electrodes were sealed using a 25-mm-thick hot-melt film (Surlyn 1702, Dupont). A small hole was drilled in the counter-electrode and electrolyte filled using a vacuum pump. All fabrication steps are described in more detail in literature.^{7,8}

S5 AS02 and C106 Dye Kinetics

A series of time resolved photoluminescent decay and transient decay measurements were used to determine the charge transfer rates of AS02 and C106. Time resolved PL measurements have traditionally been used to determine the rate of the fastest process such electron transfer to TiO₂ (kᵢₙⱼ) as well as the non-radiative decay rates (kₙᵣ) when dyes are placed on wide band gap semiconductors such as alumina that prevent electron injection. Transient decay measurements are used to determine the regeneration rate (k_{reg}) between holes in the dye with the electrolyte and the recombination rate (k_{rec}) between holes in the dye and electrons in the titania.

Time-correlated single photon counting was used to estimate the electron injection rate of AS02 on TiO₂. Measurements were performed using a 407 nm picosecond diode (Horiba Jobin Yvon NanoLED-07); all samples were measured for 1000 seconds and the results were normalized to the light absorption at the LED wavelength. Figure S5.1, of provisional application 61/516,833 filed Apr. 8, 2011, which is incorporated herein by reference, shows the time resolved PL results for AS02 in solution (DMF), on alumina (Al₂O₃) and on titania. The PL decay of AS02 was modeled as a single exponential with a lifetime of τ₀=2.75 ns. When AS02 was placed on Al₂O₃, which has a conduction band higher than the LUMO level of the AS02 in order to prevent electron injection. AS02 on Al₂O₃ exhibited monoexponential decay with a lifetime of τₙᵣ=1.46 ns. AS02 on titania experienced PL decay faster than the resolution of the instrument (˜250 ps). An injection efficiency of 86% was estimated by integrating the PL intensity of AS02/Al₂0₃ versus AS02/TiO₂ over the same amount of time (1000 seconds). Based on the injection efficiency, we would estimate that the electron injection rate of AS02 to TiO₂ (kᵢₙⱼ) would be less than 230 ps.

Figure S5.1 of provisional application 61/516,833 filed Apr. 8, 2011, which is incorporated herein by reference, shows time resolved photoluminescence decay of AS02 in DMF solution (10⁻⁵M), on Al₂0₃, and on TiO₂.

C106 has a similar chemical structure as K19, which has an electron injection rate on the 20 fs time scale when attached to TiO_{2.}⁹ The non-radiative decay lifetime is τₙᵣ=18.5 ns and was best fit using a monoexponential decay shown in figure S5.2, of provisional application 61/516,833 filed Apr. 8, 2011, which is incorporated herein by reference. C106 PL lifetime in solution was best fit using a double exponential (τ₁=85 ns (40%), and τ₁=16 ns (60%)). The long lifetime is typical of Ru based metal complex dyes¹⁰; it is suspected that the faster quenching time is a result of oxygen impurities in the DMF, which acts as an effective quencher of Ru metal complexes.¹¹

Figure S5.2 of provisional application 61/516,833 filed Apr. 8, 2011, which is incorporated herein by reference, shows time resolved photoluminescence decay of C106 on Al₂0₃ (black line) and in DMF (red line).

To determine the hole transfer from the dye to the electrolyte (k_{reg}) recombination of holes in the dye to electrons in the TiO₂ (k_{rec}) we used time resolved transient measurements of the individual dyes on TiO₂ with an without the iodide based electrolyte. Dye-sensitized, transparent nanocrystalline TiO₂ films were irradiated by nanosecond laser pulses produced by a Powerlite 7030 frequency-tripled Q-switched Nd:YAG laser (Continuum, USA) pumping an OPO-355 optical parametric oscillator (GWU, Germany) tuned at 550 nm (30 Hz repetition rate, pulse width at half-height of 5 ns). To inject on the average less than one electron per nanocrystalline TiO2 particle, the pulse fluence was attenuated to a maximum of 40 μJ cm⁻² by use of absorptive neutral density filters. The probe light from a Xe arc lamp was passed through an interference filter monochromator, various optical elements, the sample, and a grating monochromator before being detected by a fast photomultiplier tube. Averaging over ca. 2000 laser shots was necessary to obtain satisfactory signal/noise ratios.

C106 recombination rate (k_{rec}) was determined by exciting the dye at 550 nm and measuring the transient at 800 nm. The transient optical signal observed at 800 nm records the concentration of the oxidized state of the C106 dye sensitizer after ultrafast, photoinduced electron injection from the dye into the conduction band of TiO₂. In the absence of redox electrolyte, in pure MPN solvent, the decrease in the absorbance signal reflects the dynamics of the recombination of conduction-band electrons with the oxidized dye. In such conditions, a half-reaction time (t_{1/2}) of 200 μs was measured for the charge recombination (Fig. S5.3, blue trace). In the presence of an electrolyte with the same iodide/tri-iodide concentration used in the DSC, the decay of the oxidized dye accelerated markedly. t_{1/2}=3 μs was measured (Fig. S5.3, red trace), which indicates that the sensitizer was regenerated quickly and the back reaction was intercepted almost quantitatively by the mediator.

The AS02 recombination rate was previously measured for a similar chemical structure by Durrant et al. and found to have a life time of 8 ms.¹² Because the HOMO level of the Zn based naphthalocyanine dyes are above the potential of iodide regeneration does not occur (i.e. the transient lifetime is unaffected by the addition the iodide based electrolyte).

Figure S5.3 of provisional application 61/516,833 filed Apr. 8, 2011, which is incorporated herein by reference, shows temporal profiles of the transient absorbance measured at 1=800 nm upon pulsed laser excitation (1=550 nm, 5 ns full width half-maximum pulse duration, 30 Hz repetition rate) on samples comprised of C106 dye adsorbed on nanocrystalline TiO₂ films in the presence (red trace) and in the absence (blue trace) of the redox-active electrolyte. Excitation pulse energy fluence was 40 mJ cm⁻². Smooth solid lines are double exponential fits of experimental data.

S6 AS02+C106 Fractional Surface Coverage and Dye Loading

To examine the affects of sequential sensitization we used 6.5 μm thick, transparent films comprised of 17 nm TiO₂ particles. Figure S6 of provisional application 61/516,833 filed Apr. 8, 2011, which is incorporated herein by reference, shows the optical density of titania films first dipped in a 0.1 mM AS02 solution in DMF for 15 min (S6A) and 75 minutes (S6B) respectively, then rinsed in DMF, dried with N₂, and measured using UV-Vis (green lines). The films were subsequently dipped in a 0.3 mM C106 solution comprised of 10% DMF with 90% ACN:TBA (50:50 mixture by vol) for 18 hours and rinsed in acetonitrile and measured again (black lines). FIG. 2 of provisional application 61/516,833 filed Apr. 8, 2011, which is incorporated herein by reference, also contains the optical density of a C106 control device which was only dipped in C106 solutions for 18 hours (red dashed lines). Figure S6 of provisional application 61/516,833 filed Apr. 8, 2011, which is incorporated herein by reference, was used to determine the light absorption of C106 at 550 nm in order to determine the internal quantum efficiency in section S8.

In order to accurately quantify the surface coverage (Γ) of AS02 and C106 dyes on the TiO₂ surface we performed desorption measurements similar to those described in literature and in the supporting information. The C106 dyed titania control films had a peak optical density on the titania film of 1.9; when desorbed in TBAH had a peak OD in a 1 cm cuvette of 0.315, which translates into a dye surface coverage of Γ_{C106}=1.83*10⁻¹⁰ mol/cm² (or 1.10 dye/nm²). AS02 dyed films with a peak OD of 0.725 on TiO₂ had a corresponding OD of 0.465 in solution, which translates to a surface coverage of Γ_{AS02}=5.06*10⁻¹¹ mol/cm² (or 0.305 dye/nm²). The AS02 results were based on a measured molar extinction coefficient of 100,000 M⁻¹ cm⁻¹.

The surface concentration and surface fraction of each dye as well as the total dye loading relative to the C106 only control (Total Γ) was determined for AS02+C106 systems that were sequentially sensitized for various times in table 1. The surface coverage was calculated using the desorption results described above with corrected OD at the absorption peaks of C106 and AS02. The C106 control device has a surface concentration of ˜1 dye/nm². As expected increased dipping time of the NIR-ERD results in higher dye loading and higher fraction of AS02 on the TiO₂ surface. Although there is a decline in the surface concentration of the SD (from 1.05 dye/nm² to 0.73 dye/nm²), the increase in AS02 dye loading is more significant (0 dye/nm² to 0.94 dye/nm²) resulting in a 59% increase in the overall dye loading on the titania surface.

TABLE 1

| | OD | | | OD | | | |
|---|---|---|---|---|---|---|---|
| AS02 | AS02 | Γ_{AS02} | AS02 | C106 | Γ_{C106} | C106 | Total |
| Dip Time | (@ 780 | (dye/ | Fraction | (@ 550 | (dye/ | Fraction | Γ |
| (min) | nm) | nm²) | (%) | nm) | nm²) | (%) | (%) |
| 0 min | 0.00 | 0.00 | 0 | 1.81 | 1.06 | 100 | 100 |
| 5 min | 0.39 | 0.16 | 14 | 1.74 | 1.00 | 86 | 112 |
| 15 min | 0.74 | 0.31 | 25 | 1.60 | 0.93 | 76 | 118 |
| 45 min | 1.47 | 0.62 | 43 | 1.43 | 0.83 | 57 | 138 |
| 75 min | 2.24 | 0.94 | 56 | 1.26 | 0.73 | 44 | 159 |

Dipping time versus total surface coverage and fraction of dyes on 6.5 μm thick transparent titania films. The Γ_{AS02} and Γ_{C106} is the surface concentration of AS02 and C106 respectively. The fraction represents the fraction of dye on the surface while the overall surface coverage (Total Γ) is the change in the total amount of dye loading on the surface versus the C106 control.

Figure S6 of provisional application 61/516,833 filed Apr. 8, 2011, which is incorporated herein by reference, shows optical density versus wavelength for AS02 only (green line) and AS02+C106 (black line) dyed 5.6 μm thick TiO₂ films compared to C106 control device (red dashed line).

S7 Photo-induced Absorption Spectroscopy¹³ and Chemical Oxidation of AS02_ENREF_{—}5

Photoinduced absorption (PIA) spectroscopy was used to probe the photogenerated charge species in solid-state dye-sensitized solar cells, and dye-sensitized titania films. This experimental technique comprises of a white light probe beam, spectrally resolved after passing through the samples with the addition of a modulated pump light source. A 20 W halogen lamp was used as a probe source which was filtered and focused onto the sample prior to being refocused onto the slits of a double monochromator (Gemini-180). The light intensity on the sample was approximately 65 μW cm⁻². A cooled dual color solid-state detector (Si/InGaAs) was mounted on the exit slits of the monochromator. This instrument has an effective spectral range of 300-1650 nm. A dual phase lock-in amplifier (SR 830) was used to separate out the AC signal from the detectors. This signal provided the change in transmission (ΔT) as a function of wavelength. To obtain the PIA spectrum, a Lumiled 470 nm diode was modulated using the internal reference frequency of the lock-in amplifier. The pump light from the diode was focused onto the same face of the sample as the probe source but 20° off axis, with an approximate intensity of 6 mW⁻². To obtain the transmission spectra (T) a reference scan was taken with the probe beam mechanically chopped and no excitation source. All the PIA measurements were performed in air.

Chemical Oxidation of AS02 with NOBF₄ to Verify Photon Induced Transient Absorption Results

A high concentration (0.23 mM) of NOBF₄, a strong oxidizing agent, was titrated into a 10⁻⁵ M of AS02 dye in DMF to verify that the PIA signal is related to the oxidized AS02 dye species. The optical density was determined using a UV-Vis instrument with a 1 cm cuvette. Figure S7 of provisional application 61/516,833 filed Apr. 8, 2011, which is incorporated herein by reference, shows that with increasing concentration of NOBF₄ results in both a reduction in peak absorption at 780 nm and a slight increase in light absorption in the 950-1000 nm range that is consistent with the PIA analysis.

Figure S7 of provisional application 61/516,833 filed Apr. 8, 2011, which is incorporated herein by reference, shows ptical Density of 1*10⁻⁵M AS02 in DMF with various concentration of NOBF₄.

S8 EQE and IQE Reduction with Increased AS02 Surface Coverage

The EQE measurement light source was a 300 W xenon lamp (ILC Technology), which was focused through a Gemini-180 double monochromator (Jobin Yvon). EQE measurements were performed at 1% sun using a metal mask with an aperture area of 0.159 cm².

There is a reduction in the peak EQE of the C106 with the addition of AS02 on the titania surface. Increasing AS02 from 0% to 56% reduces the C106 peak EQE from 77.4% to 36.5% as shown in figure S8A of provisional application 61/516,833 filed Apr. 8, 2011, which is incorporated herein by reference. The IQE of the system was determined by peak EQE of C106 divided by the measured light absorption of the C106 at 550 nm, which was corrected for competing AS02 light absorption (see figure S6 of provisional application 61/516,833 filed Apr. 8, 2011, which is incorporated herein by reference). The IQE of the C106 control device is 89% but is significantly reduced to 47% with increased AS02 dye loading as shown in figure S8B of provisional application 61/516,833 filed Apr. 8, 2011, which is incorporated herein by reference.

Figure S8. of provisional application 61/516,833 filed Apr. 8, 2011, which is incorporated herein by reference, shows (A) External Quantum Efficiency versus wavelength for various surface concentrations of AS02 and C106. (B) Internal Quantum Efficiency of C106 at 550 nm versus fractional surface coverage.

S9 Charge Collection Efficiency of Cosensitized DSCs

Impedance spectroscopy measurements described in the manuscript were used to estimate the charge collection efficiency and shown in figure S9.1 of provisional application 61/516,833 filed Apr. 8, 2011, which is incorporated herein by reference. Near short circuit current condition (i.e. V ˜200 mV) the charge collection efficiency of the C106 control and AS02 (14%)+C106 (86%) DSC are relatively high (94%) while the DSC with a high concentration of AS02 (56%) has a η_{cc} of 83%.

Figure S9 of provisional application 61/516,833 filed Apr. 8, 2011, which is incorporated herein by reference, shows charge collection efficiency (ii) versus voltage for C106 DSCs with various concentrations of AS02 on the surface.

S10 Device Characteristics of AS02+C106 DSCs

The power of the AM 1.5 solar simulator (100 mW cm⁻²) was calibrated using a reference silicon photodiode equipped with an infrared cutoff filter (KG-3, Schott) to reduce the mismatch between the simulated light and solar spectrum from 350-700 nm to less than 2% (ref 50). The J-V curves were obtained by externally biasing the DSC and measuring the photocurrent using a Keithley 2400 digital source meter. All measurements were performed using a metal mask with an aperture of 0.159 cm2 to reduce light scattering

The C106 control device had a power conversion efficiency of 8.3% with Jsc=15.5 mA/cm², Voc=728 mV, and FF=0.74. The overall power conversion of the control device, which uses a 6.5 μm thick transparent film, is about 3% lower than the record device which uses a 10 μm transparent+5 μm scattering layer and antireflective coating to increase Jsc.¹

The overall power conversion efficiency of C106 based DSCs was reduced with increasing concentrations of AS02, as shown in figure S10A of provisional application 61/516,833 filed Apr. 8, 2011, which is incorporated herein by reference. Although AS02+C106 DSCs displayed higher EQE in the near infrared portion of the solar spectrum the EQE loss in the visible was substantial resulting in an overall loss in Jsc shown in figure S10C of provisional application 61/516,833 filed Apr. 8, 2011, which is incorporated herein by reference. The open-circuit voltage (Figure S10B of provisional application 61/516,833 filed Apr. 8, 2011, which is incorporated herein by reference) was reduced in part due to a decrease in the photocurrent density but primarily is due to increased recombination at the TiO₂ surface due to AS02. The fill factor, shown in figure S10D of provisional application 61/516,833 filed Apr. 8, 2011, which is incorporated herein by reference, remained relatively unaffected by AS02 concentration when mixed with C106.

Cosensitization of broadly absorbing Ruthenium metal complex dyes with highly absorptive near-infrared (NIR) organic dyes is a clear pathway to increase light harvesting in liquid based dye-sensitized solar cells (DSCs). In cosensitized DSCs, dyes are intimately mixed and intermolecular charge and energy transfer processes play an important role in device performance. Here we demonstrate that an organic NIR dye incapable of hole regeneration is able to produce photocurrent via intermolecular energy transfer with an average excitation transfer efficiency of over 25% when cosensitized with a metal complex sensitizing dye (SD). We also show that intermolecular hole transfer from the SD to NIR dye is a competitive process with dye regeneration, reducing the internal quantum efficiency and the electron lifetime of the DSC. This work demonstrates the general feasibility of using energy transfer to boost light harvesting from 700-800 nm and also highlights key design rules for future NIR energy relay dyes and NIR sensitizing dyes.

Dye-sensitized solar cells comprised mainly of abundant, non-toxic materials offer an inexpensive route to develop highly efficient photovoltaic cells.¹⁻⁴ Currently the most efficient sensitizing dyes are ruthenium based, metal ligand complexes (e.g. C106 and N719),^{5,6} which absorb light in the visible portion of the solar spectrum, have excellent charge injection properties, and produce a high open-circuit voltage, Voc, which is defined as greater than 750 mV. It should be possible to further increase the power conversion efficiency of DSCs by harvesting light in the near-infrared red portion of the spectrum. Cosensitization of titania by dyes with complimentary absorption spectra has been demonstrated to broaden the spectral response of organic dye based DSCs in the visible portion of the spectrum, but not beyond 720 nm.⁷⁻¹⁰ Designing near-infrared sensitizing dyes with high internal quantum efficiencies is challenging because reducing the band gap requires more precise alignment of the LUMO and HOMO levels and short conjugated ligands to facilitate charge transfer. To date only two NIR sensitizing dyes (i.e. peak absorption >700 nm) have demonstrated good charge injection efficiencies in DSCs, but neither dye has a Voc greater than 450 mV.^{11,12} Recombination from the electrons in titania with holes in the dye and triiodide in the electrolyte play a key role in determining the open-circuit voltage.¹³ Organic dyes typically experience higher recombination rates resulting in a lower Voc.¹⁴ The great challenge of designing a cosensitized DSC system using NIR-dyes will be maintaining a Voc greater than 700 mV.

Two NIR dye design strategies could result in higher power conversion efficiencies. First, it may be possible to use highly absorptive NIR-sensitizing dyes that directly inject charges even if NIR-SDs have higher recombination rates by using low surface concentrations (<10%) of NIR-SDs to minimize Voc losses. DSC systems where cosensitized dyes do not electronically interact with one another are expected to have an electron recombination rate equivalent to the weighted average of the individual dye DSC systems. However, intermolecular charge transfer from dyes with a low recombination rate to dyes with a higher recombination rate can significantly increase the overall electron recombination rate between oxidized dyes and electrons in the titania, which can disproportionately reduce the open-circuit voltage of the cosensitized DSC system.

A second strategy is to electronically insulate the NIR-dye from the TiO₂ surface to reduce the recombination rate, which would maintain the Voc but also prevent electron injection. In this case, the NIR dye would act as an energy relay dye (ERD) requiring efficient intermolecular energy transfer to the metal complex SD in order to generate photocurrent, as shown in scheme 1. In order to address the feasibility of using NIR-ERDs, we must first determine how effectively NIR-ERDs can transfer energy in a cosensitized system.

Scheme 1. The NIR dye attached to the titania surface absorbs near-infrared photons and uses short range energy transfer to excite a neighboring sensitizing dye, which is responsible for electron transfer into the TiO₂ (kᵢₙⱼ) and hole regeneration with the electrolyte (k_{reg}).

Conventional DSCs are solely dependent on charge transfer mechanisms for current generation, while plants often incorporate a variety of energy transfer processes to increase light harvesting during photosynthesis.¹⁵ Developing systems that incorporate both Förster resonant energy transfer (FRET)¹⁶ and Dexter¹⁷ energy transfer allow greater flexibility in the design of potential light harvesting candidates. Energy relay dyes (ERDs) have been used previously to increase light harvesting in the blue portion of the solar spectrum.^{18,19} Blue ERDs, which absorb high energy photons and undergo FRET to sensitizing dyes, can efficiently transfer energy when placed inside the electrolyte^{18,20} or cosensitized²¹ on nanocrystalline TiO₂. Grimes et al. recently demonstrated that ERDs unattached to the titania and slightly red shifted relative to the sensitizing dye peak absorption were able to undergo FRET to the SD.²² However, the low FRET radii (e.g. 1-4 nm) due to the poor overlap between ERD emission and SD absorption prevents efficient energy transfer from occurring when ERDs are placed inside the electrolyte.²³ For DSC systems where energy transfer is weak (i.e. FRET radii <4 nm), NIR-ERDs should be within the FRET radius of the SD to efficiently transfer energy, which requires tethering between dyes¹⁹ or cosensitization on the TiO₂ surface.

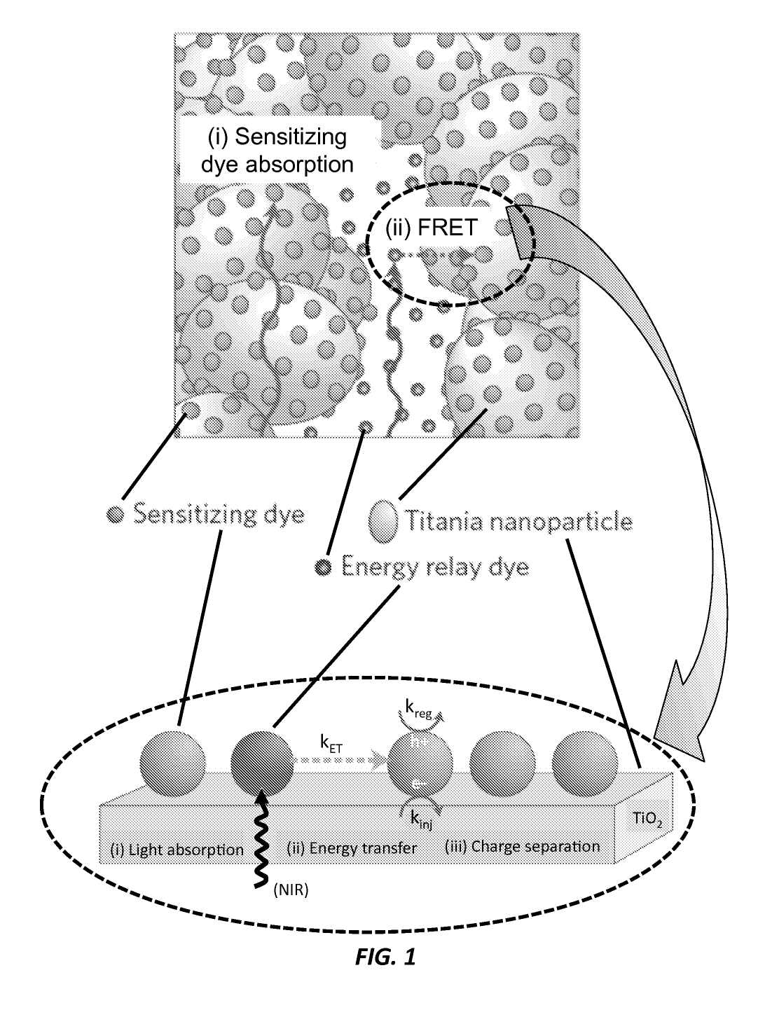

In order to verify that energy transfer occurs from the NIR-dye to the SD, we have designed a zinc naphthalocyanine based dye (AS02) that cannot regenerate with the electrolyte and produce photocurrent independently. The absorption, emission, and the chemical structure of C106 and AS02 in dimethylformamide (DMF) are shown in figure 1 of provisional application 61/516,833 filed Apr. 8, 2011, which is incorporated herein by reference. C106 has a peak molar extinction coefficient of 18,700 M⁻¹ cm⁻¹ at 550 nm with an absorption tail that extends weakly out to 800 nm.⁵ C106 has a broad emission spectrum with a peak at 786 and a natural fluorescence decay lifetime of 85 ns in DMF. The photoluminescence quantum efficiency of Ru based metal complexes is between 0.2-0.02%. AS02 has a peak molar extinction coefficient of 100,000 M⁻¹ cm⁻¹ at 773 nm with a narrow emission peak at 782 nm with a fluorescence natural decay lifetime of 2.75 ns in DMF. The photoluminescence quantum efficiency of Zn based naphthalocyanines is between 10-30%.²⁵ Photoelectron spectroscopy in air (PESA) was used to determine that the HOMO level of AS02 (−4.60 eV) is high relative to the iodide potential (−4.85 eV) which has previously been shown to prevent dye regeneration for a similar Zn based naphthalocyanine sensitizing dye;²⁶ C106 has a HOMO level of −5.27 eV.⁵ Intermolecular hole transfer is thermodynamically favorable from the C106 to the AS02; the rate of transfer will be dependent upon the HOMO level offset and the separation distance between molecules.

The Förster radius (R₀) is the distance between the donor and acceptor dye when Förster resonant energy transfer is 50% likely. The FRET R₀ from the donor to the acceptor dye is primarily determined by the donor photoluminescence quantum efficiency, the molar extinction coefficient of the acceptor, and the overlap between the donor emission and acceptor absorption spectra (see supporting information). Traditional energy transfer systems are designed to funnel energy from a donor chromophore whose absorption is blue shifted relative to the acceptor dye absorption (i.e. C106 to AS02) so that donor emission can overlap with the peak acceptor absorption to provide the largest possible FRET radius.²⁷ The FRET radius from C106 to AS02 is estimated to be between 1.5 to 2.2 nm, which is fairly short and primarily due to the low photoluminescence quantum efficiency of the C106 dye. Despite the weak emission/absorption overlap in the AS02 emission and C106 absorption, the FRET radius from the NIR-dye (AS02) to the SD (C106) is estimated to between 1.5 and 1.8 nm. The rate of Förster energy transfer (k_{FRET}) between isolated chromophores, known as point-to-point transfer, is given by k_{FRET}=k₀(R₀)⁶/r⁶, where r is the separation distance and k₀ is the natural fluorescence decay rate, k₀=1/τ₀. The separation distance can be approximated based on the sensitizing dye surface concentration, which was measured by desorbing the C106 from titania using 0.15 M tetrabutylammonium hydroxide in DMF and found to be 1 dye/nm² on the 17-nm-diamter TiO₂ nanoparticles with an estimated roughness factor of 100 μm (see supporting information). When the NIR-dye molecules intimately mix with the C106 the average separation between dyes is estimated to be approximately 1 nm. The FRET rate from the AS02 to C106 is predicted to be between 7.1*10⁹−2.3*10¹⁰ s⁻¹ (τ_{FRET,AS02}=44-130 ps) based on an average separation distance of 1 nm, while the FRET rate estimates from C106 to AS02 between 1.3*10⁸-1.3*10⁹ s⁻¹ (τ_{FRET,C106}=0.75-7.5 ns). Interestingly, the FRET rate from the NIR-dye (AS02) to the visible sensitizing dye (C106) is an order of magnitude faster than in the opposite direction due to the differences in the fluorescence decay rates between chromophores. The k_{FRET} rates should be considered rough approximations because the FRET radius calculation is based on a random orientation (i.e. dyes rotating freely in solution), which would not be the case when anchored on the TiO₂ surface. Given the short length scale, Dexter energy transfer may also play an important role in intermolecular energy transfer.²⁷ Meyer et al. have demonstrated near unity lateral Dexter energy transfer from Ru based metal complex SDs to Os based metal complex SDs across a semiconductor interface²⁸ and have also estimated Dexter energy transfer rates between Ru metal complex SDs to be on the 30 ns time scale.²⁹ Calculating the Dexter transfer rate between AS02 to C106 requires calculating the inner and outer sphere reorganization energies and is beyond the scope of this work.²⁹

The excitation transfer efficiency, ETE, is the probability that a dye will undergo energy transfer. ETE is determined by the rate of intermolecular energy transfer (k_{ET}) relative to the combined rates of all decay pathways which includes the electron injection rate (kᵢₙⱼ) and the non-radiative decay rate (kₙᵣ) of the attached dye as shown in equation (1). Hole regeneration is an alternative decay pathway, but occurs on time scales several orders of magnitude slower than energy and electron transfer and is not a major factor for iodide/triiodide based DSCs.

$$E T E = \frac{{k}_{ET}}{{k}_{ET} + {k}_{inj} + {k}_{nr}} \qquad ( 1 )$$

The rates of the AS02+C106 DSC system are shown in Scheme 2 with the rate lifetimes displayed in Table 2. Time resolved PL measurements were performed on titania and alumina films to determine electron transfer to TiO₂ (kᵢₙⱼ) and the non-radiative decay rates (kₙᵣ) respectively. For efficient sensitizing dyes, the electron injection rate is the fastest kinetic process; the kᵢₙⱼ rate of AS02 is greater than 4.3*10⁹ s⁻¹ (τ_{inj,AS02}<230 ps) and was not significantly slowed by the propionic acid ligand, while the kᵢₙⱼ rate of Ru based metal ligand based DSCs is approximately 5*10¹³ s⁻¹ (τ_{inj,C106}˜20 fs).³⁰ It should be noted that the non-radiative decay rate of both dyes is faster when attached on alumina than the fluorescence decay rate when in DMF. Transient absorption decay measurements on dyed TiO₂ films were used with and without the iodide based electrolyte to determine the regeneration rate (k_{reg}) between holes in the dye with the electrolyte and the recombination rate (k_{rec}) between holes in the dye and electrons in the titania respectively. All rates were best fit as a single exponential decay; the experimental details and data are provided in the supporting information.

Scheme 2. Jablonski Plot of AS02+C106 DSC system. The scheme is not geometrically correct (i.e. both dyes should be on the same TiO₂ surface), processes that result in photocurrent generation are labeled in black; while processes that do not contribute to photocurrent are labeled in grey; dashed lines represent intermolecular processes.

TABLE 2
Energy and Charge Transfer Lifetimes for AS02 and C106

| | | ERD | | SD | |
|---|---|---|---|---|---|
| Mechanism | Name | Lifetime | | Lifetime | |
| e⁻ injection into TiO₂ | kᵢₙⱼ | <230 | ps | 20 | fs^{(a)} |
| h+ regeneration with electrolyte | k_{reg} | — | | 3.6 | μs |
| Nonradiative recombination | kₙᵣ | 1.5 | ns | 18.5 | ns |
| e⁻ (TiO₂) recombination with h⁺ | k_{rec} | 8.0 | ms^{(b)} | 590 | μs |
| (Dye) | | | | | |
| Intermolecular h⁺ transfer | k_{HT} | — | | <5.4 | μs |
| Natural fluorescence decay | k₀ | 2.75 | ns | 85 | ns |
| in DMF | | | | | |
| Modeled Intermolecular FRET | k_{FRET} | 44-130 | ps | 0.75-7.5 | ns |

| | | | | |
|---|---|---|---|---|
| Measured Intermolecular ET | k_{ET} | <530 | ps | — |

Rates measured by ^{(a)}Grätzel et al.³⁰ and ^{(b)}Durrant et al.²⁶
The estimated k_{ET} and k_{HT} were based on measured rates and the ETE and IQE respectively.

The excitation transfer efficiency from NIR-dye to the SD is estimated to be between 60-80% based on the charge kinetics of the AS02 the FRET radius, and an average separation distance of 1 nm. DSCs cosensitized with all organic dyes have previously demonstrated an energy cascade effect, where intermolecular energy transfer occurs from the high band gap to the lower band gap SD,³¹ However, energy transfer from the metal complex SD to the NIR-dye is not likely because the rate of electron injection of C106 is several order of magnitude faster than energy transfer processes, efficiently splitting the exciton before energy transfer can occur.

In order to verify that intermolecular energy and hole transfer occurs in this DSC system we cosensitized transparent 6.5 μm thick TiO₂ mesoporous films and measured the optical and electrical properties using methods similar to literature.²⁰ Showa Denko 17-nm-diameter TiO₂ particles were deposited on fluorine-doped tin oxide glass (TEC 15 Ω/square, 2.2 mm thick, Pilkington) via screen printing, sintered at 450° C., and subsequently treated with TiCl_{4.}³² figure 1A of provisional application 61/516,833 filed Apr. 8, 2011, which is incorporated herein by reference, shows the optical density (OD) versus wavelength during different stages of cosensitization. The titania films were first dipped in a 0.1 mM AS02 solution in DMF for 15 min, then rinsed in DMF and dried with N₂ (green line). The film was subsequently dipped in a 0.3 mM C106 solution comprised of 10% DMF with 90% acetonitrile:tert-butyl alcohol (50:50 mixture by volume) for 18 hours and rinsed in acetonitrile (black line). The control DSCs were dipped in the C106 solution for 18 hours (red dashed lines). TiO₂ films dipped in AS02 for 15 min resulted in fractional surface coverage of 14% AS02 (see supporting information) with a peak optical density of 0.45 or 65% of light absorbed at 780 nm. Adding the AS02 prior to C106 sensitization does not drastically affect the overall light harvesting of the C106 sensitizer. The peak OD of the C106 control device is 1.83 (98.5% light absorption) versus 1.74 (98.2% light absorption) at 550 nm for the AS02 (14%)+C106 (86%) system. Figure 2A of provisional application 61/516,833 filed Apr. 8, 2011, which is incorporated herein by reference also shows a slight red shifting of both the AS02 and a C106 peak which is likely caused by molecular orbital overlap between NIR-dye. The redshift was not caused by solvatochromatic effects; changing from DMF to acetonitrile:tert-butyl alcohol mixture resulted in a slight blue shift in the absorption peak of the AS02 sensitized on TiO₂. The AS02 peak shape and intensity does not change during sequential sensitization which indicates that the AS02 molecules do not aggregate or desorb while being dipped in the C106 solution.

Dye-sensitized solar cells were assembled and tested using standard methods previously described in detail in literature with an electrolyte comprised of 1.0 M 1,3-dimethylimidazolium iodide, 0.03 M iodide, 0.1 M guanidinium thiocyante, 0.5 M tert-butylpyridine in acetonitrile valoronitrile (85:15 v/v).^{5,33} External quantum efficiency (EQE) measurements were used to verify intermolecular energy and hole transfer. The EQE at 780 nm is 10.2% for AS02+C106 DSC and 0.8% for the C106 control as shown in figure 2B of provisional application 61/516,833 filed Apr. 8, 2011, which is incorporated herein by reference. The EQE contribution from AS02 is the direct result of energy transfer from the AS02 to the C106. The EQE of AS02 only DSCs (green line) showed no photoresponse at 780 nm; the EQE generated below 450 nm is a result of light absorption by the titania. The C106 peak EQE (550 nm) is significantly reduced with the addition of AS02 on the titania surface. The EQE reduction is due to intermolecular hole transfer from the C106 dye to the AS02. The internal quantum efficiency of the control device was determined to be 88.8% for the C106 control and 72.1% with light (14%) AS02 surface coverage.

The average excitation transfer efficiency, E̅T̅E̅, defined as the fraction of excited NIR-ERDs that undergo energy transfer to the SD, is described by equation (2).

EQE_{ERD}=η_{ABS,ERD}.IQE. E̅T̅E̅ (2)

Where EQE_{ERD} is the external quantum efficiency contribution caused by the NIR-ERD at 780 nm (9.4%), η_{ABS,ERD} is the fraction of light absorbed by the NIR-ERD, IQE is the internal quantum efficiency. The η_{ABS,ERD} was determined to be 50.8% when correcting for light losses related to reflection (4%) and FTO light absorption (11%) at 780 nm.²⁰ Light absorption by C106 at 780 nm was considered negligible. The estimated E̅T̅E̅ was determined to be 26%; it should be noted that the measured IQE (72.1%) is an average value of all C106 dyes, but the IQE is most likely lower for C106 dyes that are in close proximity to AS02, which have a higher probability of transferring holes to the AS02 before dye regeneration. Thus the calculated E̅T̅E̅ represents the minimum bound estimate for the AS02+C106 DSC system. AS02 is not an ideal NIR-ERD because the electron injection rate (τᵢₙⱼ<230 ps) is competitive with energy transfer which reduces the excitation transfer efficiency. For NIR-ERDs with LUMO levels above the conduction band of TiO₂ an insulating ligand should be added to retard charge injection.²¹ If AS02 electron injection is significantly retarded then the E̅T̅E̅ would increase to over 70%. The measured energy transfer rate (k_{ET}) is a combination of both Dexter and FRET energy transfer. Based on the kᵢₙⱼ and kₙᵣ of AS02 and the minimum bound E̅T̅E̅ of 26%, the measured rate of energy transfer (k_{ET}) is >1.76*10⁹ s⁻¹ (τ_{ET}<568 ps) using equation 1.

Photo-induced transient absorption (PIA) spectroscopy, shown in figure 3 of provisional application 61/516,833 filed Apr. 8, 2011, which is incorporated herein by reference, was performed on C106, AS02+C106, and AS02 sensitized films without the presence of the electrolyte to probe the photogenerated charge species. Steady-state PIA, which measures the change in absorption of the oxidized dye species, was chopped at a frequency of 9 Hz using a 470 nm light bias using methods previously described in literature.³⁴ Briefly, the C106 cation (red dash dot) bleaches at 550 nm and has enhanced absorption at 800 nm, while the AS02 cation (green) bleaches at 780 nm and has an absorption increase at 1000 nm. For AS02+C106 dyed (black) films, the C106 absorbs over 80% of the photons at the illumination wavelength (470 nm), but the PIA signal is dominated by the AS02 cation. AS02 is an ideal dye to measure the fraction of holes from C106 dyes that transfer to NIR-dyes in the cosensitized DSC system. Charge transfer between SDs in cosensitized systems has been previously discussed,^{10,31} but could not be verified nor quantified because both dyes are capable of hole regeneration. Because AS02 cannot regenerate with the electrolyte, all holes transferred to AS02 must recombine with the electrons in the TiO₂ and cannot contribute to photocurrent. For this system the fraction of holes from C106 that transfer to AS02 can be estimated based on the reduction in the internal quantum efficiency of the AS02+C106 DSC. The internal quantum efficiency is defined by equation (3), which can be defined as the probability of hole transfer to the electrolyte, electron transfer to the titania, and the charge collection efficiency (η_{CC}). For C106, the electron injection rate is extremely fast relative to the nonradiative decay rate and is not expected to change with cosensitization. The η_{CC} was estimated to be 94% for C106 only but was reduced to 83% for the AS02 (56%)+C106 (44%) DSC system (see supporting information). Further changes in the IQE will be primarily due to competition between hole transfer (k_{HT}) and regeneration (k_{reg}) of the oxidized dye by the electrolyte.

$$I Q E = \frac{{k}_{reg}}{{k}_{HT} + {k}_{reg} + {k}_{rec}} \cdot \frac{{k}_{inj}}{{k}_{inj} + {k}_{nr}} \cdot {η}_{cc} \qquad ( 3 )$$

An equivalent surface concentration of AS02 reduced the IQE from 88% for the C106 control to 47% for AS02 (56%)+C106 (44%) DSC (see supporting information). Based on the IQE and η_{CC} reduction and C106 k_{reg} and k_{rec} rates, the effective hole transfer lifetime, τ_{HT}, is 5.4 μs. It should be noted that this is an averaged rate over all C106 dyes cosensitized on the TiO₂ surface; the intermolecular hole transfer rate may significantly vary depending on how C106 and AS02 pack with one another on the surface. While the IQE reduction caused by AS02 is an extreme case, regeneration rates can be slower for organic dyes and NIR dyes in particular will likely have a lower driving force for hole regeneration.^{35,36} The k_{HT} indicates that >40% holes can be transferred from C106 dyes near AS02. Intermolecular hole migration to NIR-dyes have important implications for Voc.

A 80 mV drop in Voc was observed for the cosensitized AS02 (14%)+C106 (86%) DSC (Voc=650 mV) system relative to the C106 control DSC (Voc=730 mV) (see supporting information). Because the Voc is also affected by the reduction in the photocurrent density, the electron lifetime was studied to determine the effects of intermolecular hole migration on the recombination. The electron lifetime was measured using electronic impedance spectroscopy for various fractional AS02/C106 surface concentrations to better understand the change in Voc. Impedance measurements were performed with an Autolab PGSTAT30 (EcoChemie B.V., Utrecht, Netherlands) over a frequency range from 1 MHz down to 0.1 Hz at bias potentials between −0.2 to −0.8 V (with a 10 mV sinusoidal AC perturbation); all measurements were done at 20° C. and in the dark. The resulting impedance spectra were analysed with ZView software (Scribner Associate Inc) on the basis of the two channel transmission line model.³⁷ The electron lifetimes of various AS02+C106 cosensitized DSC systems are plotted against conductivity and shown in FIG. 4 of provisional application 61/516,833 filed Apr. 8, 2011, which is incorporated herein by reference. C106 only DSCs have an electron lifetime of 500 ms, while AS02 only DSCs have an electron lifetime of 2 ms near open-circuit voltage conditions. If the dyes do not electronically interact in the cosensitized DSC system then one might expect that the electron decay rate to be the weighted average of the individual dye systems. However in the AS02 (14%)+C106 (86%) cosensitized DSC system, the electron lifetime is 50 ms, which is nearly three times lower than weighted lifetime of 140 ms. The disproportionate change in electron lifetime may be caused by hole transfer from the C106 to AS02. The Voc change is not related to a reduction in the overall dye loading on the TiO₂, which actually increases during cosensitization (See supporting information). It should be noted that recombination between electrons in the titania and the I₃⁻electrolyte is considered to be the Voc determining recombination mechanism when using Ru based metal complex dyes, which have relatively fast regeneration rates.^{13,38} However, recombination from electrons in TiO₂ to oxidized dye species may become the critical mechanism for NIR-dyes whose ground state redox potentials are less favorable for regeneration. A complete study of the recombination kinetics of fully functioning NIR-SD is required to determine which recombination mechanism plays a dominant role under Voc conditions for cosensitized DSC systems.

This study demonstrates the need to refine design rules for NIR-SDs and NIR-ERDs. NIR-SDs should have sufficient LUMO and HOMO levels for charge injection and a high molar extinction coefficient (>100,000 M⁻¹ cm⁻¹). Planar NIR-SDs that pack well with metal ligand SDs may lose substantial Voc due to intermolecular hole transfer, negating the potential power conversion efficiency gain with high Voc losses. NIR-SDs should be physically separated from the metal complex SD either via long alkyl side chains or selective positioning^{9,39} to prevent intermolecular hole transfer in order to maintain high open-circuit voltage.

NIR-ERDs do not require precise LUMO level alignment and short conjugated ligands for rapid electron charge injection. However NIR-ERDs must intimately mix with metal complex sensitizing dyes in order to efficiently transfer energy and must therefore have a HOMO level below the iodide potential to regenerate with the electrolyte. Ideally, NIR-ERDs should be designed with an insulating ligand that is long enough to prevent electron transfer²¹ and lower recombination, but short enough to enable close range interactions with the SD. NIR-ERD should have peak absorption between 720-790 nm and peak emission between 730-800 nm. Dyes with lower band gaps (i.e. dyes with an emission peak >820 nm) would most likely not work as NIR-ERDs with ruthenium based SDs. The ability to both sensitize and transfer energy from NIR-ERDs to metal complex sensitizing dyes allows us to expand the light harvesting out to 800 nm, which has the potential to produce 14% efficient DSCs in the future.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. All such variations are considered to be within the scope and spirit of the present invention as defined by the following claims and their legal equivalents.

What is claimed:

1. A solar cell system, comprising:
a. a nanostructured semiconductor;
b. a hole conducting medium, wherein said hole conducting medium comprises an electrolyte medium or a solid-state medium;
c. a pair of electrodes; and
d. a dye cosensitized with a metal complex sensitizing dye, wherein said cosensitized dye absorbs NIR light, wherein said NIR light undergoes energy transfer to said metal complex dye, wherein said metal complex dye separates charges and produces photocurrent to said electrode.
